(19) United States
(12) Patent Application Publication
(10) Pub. No.: US 2017/0278847 A1
(43) Pub. Date: Sep. 28, 2017

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Dong Oh KIM, Daegu (KR); Chan Sic YOON, Anyang-si (KR); Ki Seok LEE, Busan (KR); Yong Jae KIM, Seoul (KR)

(21) Appl. No.: 15/461,726

(22) Filed: Mar. 17, 2017

(30) Foreign Application Priority Data
Mar. 22, 2016 (KR) 10-2016-0034026

(51) Int. Cl. H01L 27/108; H01L 23/528; H01L 29/06

(52) U.S. Cl. CPC H01L 27/10814; H01L 29/0696; H01L 27/10844; H01L 23/528

(57) ABSTRACT

A semiconductor device includes a substrate including a cell area and a background area, the background area surrounding the cell area, a plurality of active patterns in the cell area along a first direction, the active patterns being defined by a device isolation layer, and a background pattern filling the background area to surround the cell area, wherein the active patterns include a first active pattern most adjacent to an edge of the cell area, and a second active pattern separated from the first active pattern in a second direction intersecting the first direction, the second active pattern being separated from the background area.

### CROSS-REFERENCE TO RELATED APPLICATION

Korean Patent Application No. 10-2016-0034026, filed on Mar. 22, 2016, in the Korean Intellectual Property Office, and entitled: “Semiconductor Device and Method of Manufacturing the Same,” is incorporated by reference herein in its entirety.

### BACKGROUND

### 1. Field

The present disclosure relates to a semiconductor device and a method of manufacturing the same, and more particularly, to a semiconductor device which includes an active pattern separated from a background area and a method of manufacturing the semiconductor device.

### 2. Description of the Related Art

As semiconductor devices have higher capacity and become more highly integrated, design rules are changing. The change in design rules is also occurring in dynamic random access memories (DRAMs) which are one type of memory semiconductor devices.

With the change toward finer design rules, the alignment state of contact holes or active patterns have an important influence on the operation reliability of a semiconductor device. To ensure the alignment of contact holes or active patterns, patterning using self-aligned contact holes or patterns is performed in a process of manufacturing a semiconductor device.

### SUMMARY

According to an aspect of the present disclosure, there is provided a semiconductor device including a cell area which is defined in a substrate and a background area which surrounds the cell area, a plurality of active patterns which are disposed in the cell area, are defined by a device isolation layer, and extend along a first direction, and a background pattern which fills the background area to surround the cell area, wherein the active patterns comprise a first active pattern which is most adjacent to an edge of the cell area; and a second active pattern which is separated from the first active pattern in a second direction intersecting the first direction and separated from the background area.

According to another aspect of the present disclosure, there is provided a semiconductor device including a cell area which is defined in a substrate and a background area which surrounds the cell area, a plurality of active patterns which are disposed in the cell area of the substrate and extend along a first direction to be separated from each other in the first direction, and a first space and a second space which are respectively disposed between the active patterns and are arranged alternately, wherein at least one of the active patterns is separated from the background area by the second space.

According to yet another aspect of the present disclosure, there is provided a semiconductor including a substrate including a cell area and a background area, the background area surrounding the cell area, a plurality of active patterns in the cell area along a first direction, the active patterns including a first active pattern most adjacent to an edge of the cell area, and a second active pattern separated from the first active pattern in a second direction intersecting the first direction, a background pattern in the background area, a portion of the background pattern extending from the background area into the cell area to define a nonlinear boundary between the background area and the cell area, the portion of the background pattern extending into the cell area contacting the second active pattern.

### BRIEF DESCRIPTION OF THE DRAWINGS

Features will become apparent to those of ordinary skill in the art by describing in detail exemplary embodiments with reference to the attached drawings, in which:

FIG. 1 illustrates a top view of a semiconductor device according to an embodiment of the present disclosure;

FIG. 2 illustrates a cross-sectional view taken along line A-A′ of FIG. 1;

FIG. 3 illustrates a top view of a semiconductor device according to another embodiment of the present disclosure;

FIGS. 4A through 10B illustrate views of stages in a method of manufacturing a semiconductor device according to an embodiment of the present disclosure.

### DETAILED DESCRIPTION

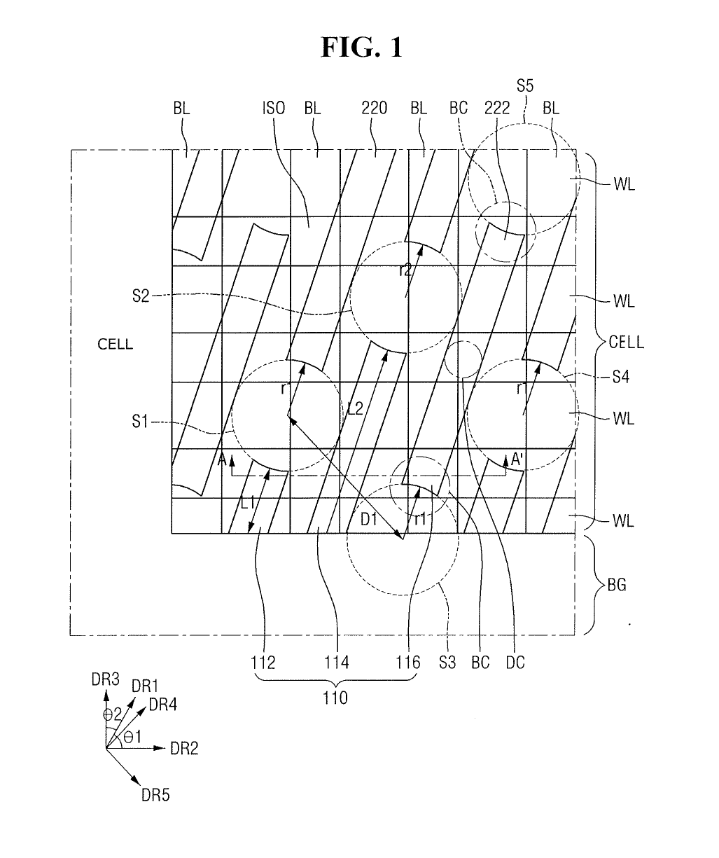

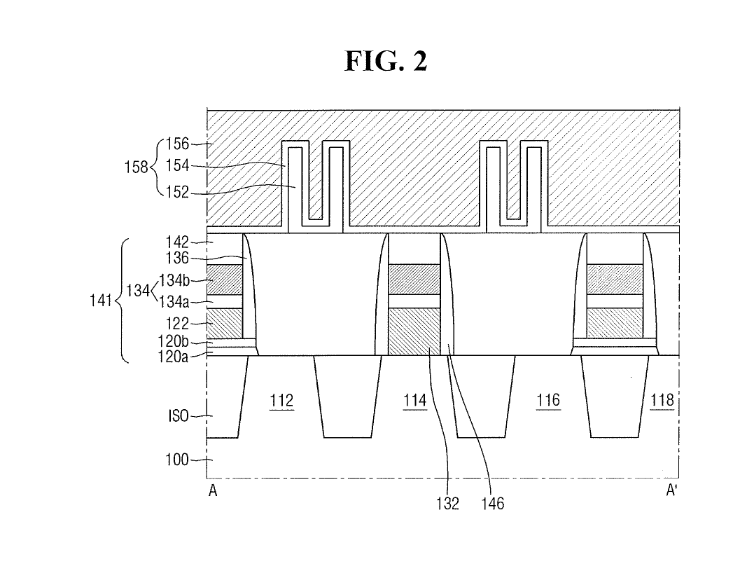

FIG. 1 is a top view of a semiconductor device according to an embodiment of the present disclosure. FIG. 2 is a cross-sectional view taken along line A-A′ of FIG. 1.

Referring to FIGS. 1 and 2, a semiconductor device according to the current embodiment includes a substrate 100, in which a cell area ACT and a background area BG are defined. Further, the semiconductor device according to the current embodiment includes a plurality of active patterns 110, a plurality of spaces, e.g., first through fourth spaces S1 through S4, bit lines BL, word lines WL, and a device isolation area ISO in the cell area ACT.

For example, the substrate 100 may be a bulk silicon substrate or a silicon-on-insulator (SOI) substrate. In another example, the substrate 100 may be a silicon substrate or a substrate made of another material, e.g., silicon germanium, indium antimonide, lead telluride, indium arsenide, indium phosphide, gallium arsenide or gallium antimonide. In yet another example, the substrate 100 may include, e.g., consist of, a base substrate and an epitaxial layer formed on the base substrate. The silicon substrate will hereinafter be described as an example of the substrate 100.

The cell area ACT and the background area BG may be defined in the substrate 100. The cell area ACT may be an area in which memory cells are formed in the semiconductor device according to the embodiment of the present disclosure. The background area BG may, e.g., completely, surround the cell area ACT. The background area BG may be filled with a background pattern. The active patterns 110 may not be defined in the background area BG.

The active patterns 110 may be defined in the cell area ACT. That is, the device isolation area ISO may be formed in the substrate 100 to define the active patterns 110. Each of the active patterns 110 may have an isolated shape and extend in a first direction DR1 when seen from above, e.g., when seen in a top view. The active patterns 110 may include a first active pattern 112, a second active pattern 116, and a third active pattern 114 which are separated from one another.

The first active pattern 112 may be most adjacent to an edge of the cell area ACT and extend in the first direction DR1. When the first active pattern 112 is “most adjacent” to the edge of the cell area ACT, no other active patterns may be present between the edge of the cell area ACT and the first active pattern 112.

The first active pattern 112 may contact the background area BG. That is, the first active pattern 112 may extend in the first direction DR1 from a boundary between the background area BG and the cell area ACT.

A fourth active pattern 220 may be separated from the first active pattern 112 in the first direction DR1, e.g., the fourth active pattern 220 may be aligned with the first active pattern 112 to be collinear with each other while being separated from each other. The fourth active pattern 220 and the first active pattern 112 may respectively have ends facing each other. An end of the first active pattern 112 and an end of the fourth active pattern 220 which faces the end of the first active pattern 112 may be concave toward respective centers of the first active pattern 112 and the fourth active pattern 220. In detail, an end of the first active pattern 112 and an end of the fourth active pattern 220 which faces the end of the first active pattern 112 may have the same radius of curvature, e.g., and may curve away from each other.

The first space S1 may be formed between the first active pattern 112 and the fourth active pattern 220, e.g., the first space S1 may separate the first active pattern 112 from the fourth active pattern 220. Referring to FIG. 1, the first space S1 may be shaped like a circle having a first radius r1. However, the shape of the first space S1 is not limited to the circular shape. That is, the first space S1 may also be shaped like an oval having a long radius and a short radius according to the shape of a mask pattern for forming the first space S1.

The second active pattern 116 may be separated from the first active pattern 112 in a second direction DR2 and extend in the first direction DR1. The second active pattern 116 may not contact the background area BG. That is, the second active pattern 116 may be separated from the boundary between the background area BG and the cell area ACT.

The third active pattern 114 may be disposed between the first active pattern 112 and the second active pattern 116. A length L2 of the third active pattern 114 in the first direction DR1 may be greater than a length L1 of the first active pattern 112 in the first direction DR1.

A fifth active pattern 222 may be separated from the third active pattern 114 in the first direction DR1, e.g., the fifth active pattern 222 may be aligned with the third active pattern 114 to be collinear with each other while being separated from each other. The fifth active pattern 222 and the third active pattern 114 may respectively have ends facing each other. An end of the third active pattern 114 and an end of the fifth active pattern 222 which faces the end of the third active pattern 114 may be concave toward respective centers of the third active pattern 114 and the fifth active pattern 222. In detail, an end of the third active pattern 114 and an end of the fifth active pattern 222 which faces the end of the third active pattern 114 may have the same radius of curvature.

The second space S2 may be formed between the third active pattern 114 and the fifth active pattern 222, e.g., the second space S2 may separate the third active pattern 114 from the fifth active pattern 222. As will be described below, the second space S2 may be formed as a self-aligned space in a process of manufacturing a semiconductor device according to an embodiment of the present disclosure. That is, the second space S2 may be self-aligned in an area defined by sidewalls of neighboring mask patterns that surround the second space S2. The second space S2 may be shaped like a circle having a second radius r2. However, the shape of the second space S2 is not limited to the circular shape. That is, the second space S2 may also be shaped like an oval having a long radius and a short radius according to the shape of the neighboring mask patterns that surround the second space S2.

The first, second, and third active patterns 112, 116, and 114 may be separated by equal distances in the second direction DR2. Likewise, the first, second, and third active patterns 112, 116, and 114 may be separated by equal distances in a third direction DR3.

The second space S2 and the third space S3 may be substantially identical. That is, the third space S3 may also be formed as a self-aligned space by a method of manufacturing a semiconductor device of the present disclosure which will be described later. Therefore, the radius r2 of the second space S2 and a radius r3 of the third space S3 may be the same. Here, the concept that the radius r2 of the second space S2 and the radius r3 of the third space S3 are the same includes a case where a slight error occurs due to, e.g., a fine difference in the flow of an etching solution in the process of manufacturing a semiconductor device. The second space S2 and the third space S3 may be arranged side by side, e.g., and spaced apart from each other, in the third direction DR3.

The radius r1 of the first space S1 may be different from the radius r2 of the self-aligned second space S2. In addition, a fifth space S5 disposed in the same direction as the first space S1 and the second space S2 may be formed by a general mask patterning method. The first space S1, the second space S2, and the fifth space S5 arranged sequentially, e.g., aligned, in a fourth direction DR4 may show a pattern in which a space formed by a general mask patterning method and a self-aligned space are arranged alternately. For example, as illustrated in FIG. 1, the aligned arrangement of the first space S1, the second space S2, and the fifth space S5 along the fourth direction DR4 may be parallel to an aligned arrangement of the third space S3 and the fourth space S4 along the fourth direction DR4, e.g., the first and third spaces S1 and S3 may be separated from each other along a fifth direction DR5, e.g., orthogonal to the fourth direction DR4. For example, as further illustrated in FIG. 1, the first and fourth spaces S1 and S4 may be aligned along the second direction DR2.

At least part of the third space S3 may overlap the background area BG. The third space S3 may define an area which protrudes from the background area BG toward the cell area ACT. That is, the background pattern that fills the background area BG may extend beyond the background area BG into the cell area ACT to fill the third space S3.

The word lines WL may traverse the active patterns 110. The bit lines BL may extend along the second direction DR2 which forms an acute angle with the first direction DR1, and the word lines WL may extend along the third direction DR3.

Here, when “a specific direction forms a specific angle with another specific direction,” the specific angle may be a smaller one of two angles formed by the intersection of the two directions. For example, when angles formed by the intersection of two directions are 120 degrees and 60 degrees, the specific angle may be 60 degrees. Therefore, as illustrated in FIG. 1, an angle formed by the first direction DR1 and the second direction DR2 is θ1, and an angle formed by the first direction DR1 and the third direction DR3 is θ2.

Here, θ1 and/or θ2 is formed as an acute angle in order to secure a maximum gap between a bit line contact 132, which connects each of the active patterns 110 to a bit line BL, and a storage node contact 141, which connects each of the active patterns 110 to a capacitor 158. For example, θ1 and θ2 may be, but are not limited to, 45 degrees and 45 degrees, 30 degrees and 60 degrees, or 60 degrees and 30 degrees, respectively.

Each of the active patterns 110 may include a first contact area DC in an upper surface of a central part thereof, i.e., an upper surface of a part that intersects a bit line BL. In addition, each of the active patterns 110 may include a second contact area BC in upper surfaces of both ends thereof. That is, the first contact area DC is an area in which the bit line contact 132 connecting the bit line BL to the active pattern 110 is located, and the second contact area BC may be an area in which the storage node contact 141 electrically connecting the active pattern 110 to the capacitor 158 is located.

The device isolation area ISO may be filled with a material, e.g., silicon oxide or silicon nitride. The active patterns 110 may be defined by the device isolation area ISO. The device isolation area ISO may be formed in a trimming process of the active patterns 110 of the semiconductor device according to the embodiment of the present disclosure.

The bit line contact 132 may be formed in the first contact area DC to be electrically connected to the bit line BL. The bit line contact 132 may include a doped semiconductor material, conductive metal nitride, a metal, or a metal-semiconductor compound.

The storage node contact 141 may have a stacked structure. In detail, referring to FIG. 2, the storage node contact 141 may include a pad insulation layer 120a, an etch stop layer 120b, a first conductive layer 122, a second conductive layer 134, a hard mask pattern 142, and a bit line spacer 136.

The pad insulation layer 120a may be disposed at the bottom of the storage node contact 141 to electrically insulate the bit line BL from a structure thereunder. The pad insulation layer 120a may not be formed in the first contact area DC in which the bit line contact 132 is formed, e.g., so the bit line contact 132 may directly contact the active pattern 110. The pad insulation layer 120a may include, e.g., silicon oxide.

The etch stop layer 120b may be formed, e.g., directly, on the pad insulation layer 120a. The etch stop layer 120b may include a material that has a high etch selectivity with respect to the pad insulation layer 120b. The etch stop layer 120b may include, e.g., silicon nitride. The etch stop layer 120b can prevent the pad insulation layer 120a located thereunder from being etched during the formation of the bit line BL.

The first conductive layer 122 may be formed, e.g., directly, on the etch stop layer 120b. The first conductive layer 122 may include a material that can be etched easily. For example, the first conductive layer 122 may include polycrystalline silicon. Upper surfaces of the first conductive layer 122 and the bit line contact 132 may be at the same height relative to a bottom of the substrate 100.

The second conductive layer 134 may be formed, e.g., directly, on the first conductive layer 122, e.g., and on the bit line contact 132. The second conductive layer 134 may have lower resistance than the first conductive layer 122. The second conductive layer 134 may include a first metal layer 134a and a second metal layer 134b. The first metal layer 134a and the second metal layer 134b may be stacked sequentially on the first conductive layer 122, e.g., and on the bit line contact 132. The first metal layer 134a may be formed by stacking one or two or more of, but not limited to, titanium, titanium nitride, tantalum and tantalum nitride, and the second metal layer 134b may include, but not limited to, tungsten.

The hard mask pattern 142 may be formed, e.g., directly, on the second conductive layer 134. The hard mask pattern 142 may extend in the third direction DR3 and be formed to pattern the line shape of the bit line BL. In detail, the hard mask pattern 142 may function as a mask used to pattern the line shape of the first conductive layer 122 and the second conductive layer 134. The hard mask pattern 142 may include, e.g., silicon nitride.

The bit line spacer 136 may be formed on both, e.g., opposite, sidewalls of the bit line BL. That is, the bit line spacer 136 may be formed on sidewalls of the first conductive layer 122 and the second conductive layer 134 to electrically insulate the storage node contact 141 and the bit line contact 132 from each other. An insulation spacer 146 may also be formed on both sidewalls of the bit line contact 132 in the first contact area DC. The bit line spacer 136 may include, but not limited to, silicon nitride (SiN) or silicon oxycarbonitride (SiOCN).

The storage node contact 141 may be formed in the second contact area BC of each of the active patterns 110. The storage node contact 141 may electrically connect the second contact area BC and the capacitor 158, e.g., via the bit line BL. The storage node contact 141 may include a conductive material, e.g., a doped semiconductor material, conductive metal nitride, a metal, or a metal-semiconductor compound.

The capacitor 158 may contact an upper surface of the storage node contact 141. The capacitor 158 may be a metal-insulator-metal (MIM) capacitor in which a lower electrode 152, a dielectric layer 154, and an upper electrode 156 are stacked sequentially.

The lower electrode 152 may be a layer made of a conductive material. The lower electrode 152 may be made of, but not limited to, TiN, TiALN, TaN, W, WN, Ru, RuO₂, SrRuO₃, Ir, IrO₂, Pt, or a combination thereof. The lower electrode 152 may be formed by, e.g., physical vapor deposition (PVD), chemical vapor deposition (CVD), or atomic layer deposition (ALD).

The dielectric layer 154 may be, e.g., conformally, formed on the lower electrode 152. In FIG. 2, the dielectric layer 154 is illustrated as a single layer. However, the dielectric layer 154 is not limited to the single layer. For example, the dielectric layer 154 may include, e.g., consist of, a metal nitride layer and a metal oxide layer stacked on the metal nitride layer. Here, each of the metal nitride layer and the metal oxide layer may be, formed by ALD. In addition, the dielectric layer 154 is not limited to a double layer and can include, e.g., consist of, three or more layers as desired.

The dielectric layer 154 may have a high dielectric constant. For example, the dielectric layer 154 may be, but is not limited to, a single layer or a combination of layers, e.g., at least one of a ZrO₂ layer, an HfO₂ layer, and a Ta₂O₃ layer. Alternatively, the dielectric layer 154 may additionally include an aluminum nitride (AIN) layer, a boron nitride (BN) layer, a zirconium nitride (Zr₃N₄) layer, a hafnium nitride (Hf₃N₄) layer, etc.

The upper electrode 156 may be formed on the dielectric layer 154 to contact the dielectric layer 154. The upper electrode 156 may include conductive metal nitride, e.g., one of titanium nitride (TiN), zirconium nitride (ZrN), aluminum nitride (AIN), hafnium nitride (HfN), tantalum nitride (TaN), niobium nitride (NbN), yttrium nitride (YN), lanthanum nitride (LaN), vanadium nitride (VN), and manganese nitride (Mn₄N).

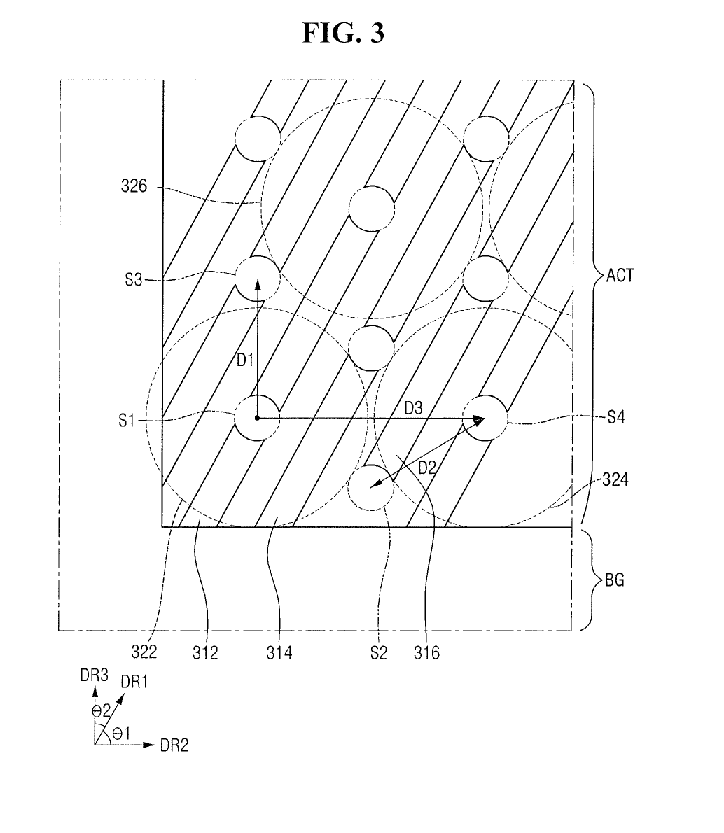

FIG. 3 is a top view of a semiconductor device according to another embodiment of the present disclosure. In FIG. 3, for ease of description, bit lines BL and word lines WL are not illustrated to focus on active patterns 310 and first through fourth spaces S1 through S4.

Referring to FIG. 3, the first through fourth spaces S1 through S4 of the semiconductor device according to the current embodiment may be arranged in a honeycomb shape.

The honeycomb shape may be a shape that can increase the integration density of the first through fourth spaces S1 through S4 to the maximum. That is, an increase in the integration density of the first through fourth spaces S1 through S4 leads to an increase in the integration density of the active patterns 310 separated from each other. Accordingly, this can increase the overall integration density of the semiconductor device and improve the operation reliability of the semiconductor device.

First, second and third patterns 322, 324 and 326 are mask patterns used to form the first through fourth spaces S1 through S4. The first space S1 and the fourth space S4 are formed using the first pattern 322 and the second pattern 324 as etch masks, and the second and third spaces S2 and S3 are self-aligned spaces defined by outer sidewalls of the first, second and third patterns 322, 324 and 326.

A distance D1 between the first space S1 and the third space S3 may be equal to a distance D2 between the second space S2 and the fourth space S4. That is, spaces formed using the first and third patterns 322 and 326 as etch masks may respectively be separated from self-aligned spaces by equal distances. On the other hand, a distance D3 between the first space S1 and the fourth space S4 may be greater than the distance D1 between the first space S1 and the third space S3 or the distance D2 between the second space S2 and the fourth space S4.

The second space S2 may define an area which protrudes from a background area BG toward a cell area ACT. A background pattern that fills the background area BG may extend beyond the background area BG to fill the third space S3.

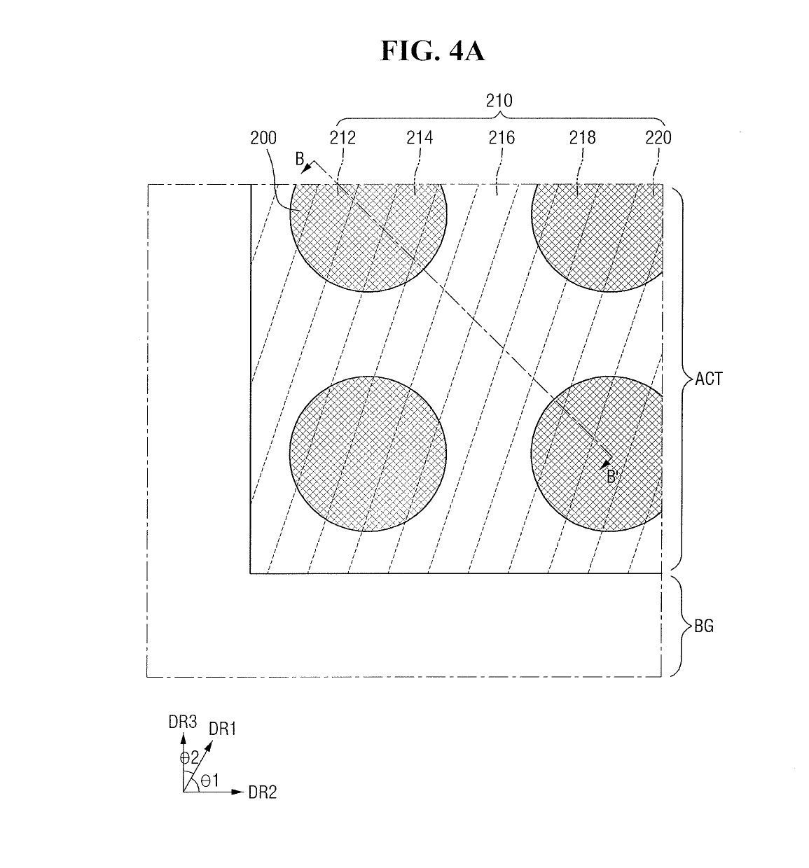

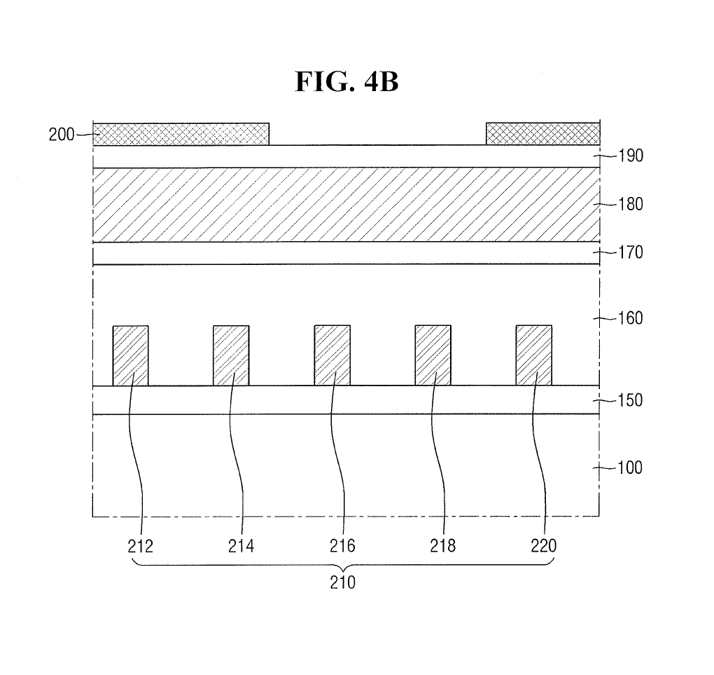

FIGS. 4A through 10B are views illustrating steps of a method of manufacturing a semiconductor device according to an embodiment of the present disclosure. Specifically, FIGS. 4A, 5A, 6A, 7A, 8A, 9A, and 10A are top views illustrating stages in the method of manufacturing the semiconductor device, and FIGS. 4B, 5B, 6B, 7B, 8B, 9B, and 10B are cross-sectional views taken along line B-B′ of FIGS. 4A, 5A, 6A, 7A, 8A, 9A, and 10A, respectively.

Referring to FIGS. 4A and 4B, the substrate 100 having the background area BG and the cell area ACT is provided. The cell area ACT of the substrate 100 may include an active layer 150 and a plurality of bars 210 disposed on the active layer 150, e.g., bars 212 through 220. The bars 210 may contact the background area BG and extend along the first direction DR1, e.g., the bars 210 may be parallel to each other. The bars 210 may be arranged at predetermined intervals.

First mask layers 160 and 170 and second mask layers 180 and 190 are stacked sequentially to cover the bars 210. A photosensitive layer pattern 200 is formed on the second mask layers 180 and 190. In some cases, an anti-reflection layer may further be formed between the second mask layers 180 and 190 and the photosensitive layer pattern 200. Each of the first mask layers 160 and 170, and the second mask layers 180 and 190 may be made of at least one of a silicon-containing material, e.g., silicon oxide (SiOₓ), silicon oxynitride (SiON) or silicon nitride (SiₓN_{y}), and a carbon-containing material, e.g., spin-on-hardmask (SOH).

The photosensitive layer pattern 200 may be patterned by a photolithography process. The photosensitive layer pattern 200 may be photoresist used in a photolithography process. The photosensitive layer pattern 200 may be formed in a circular or oval shape according to the shape of spaces to be formed.

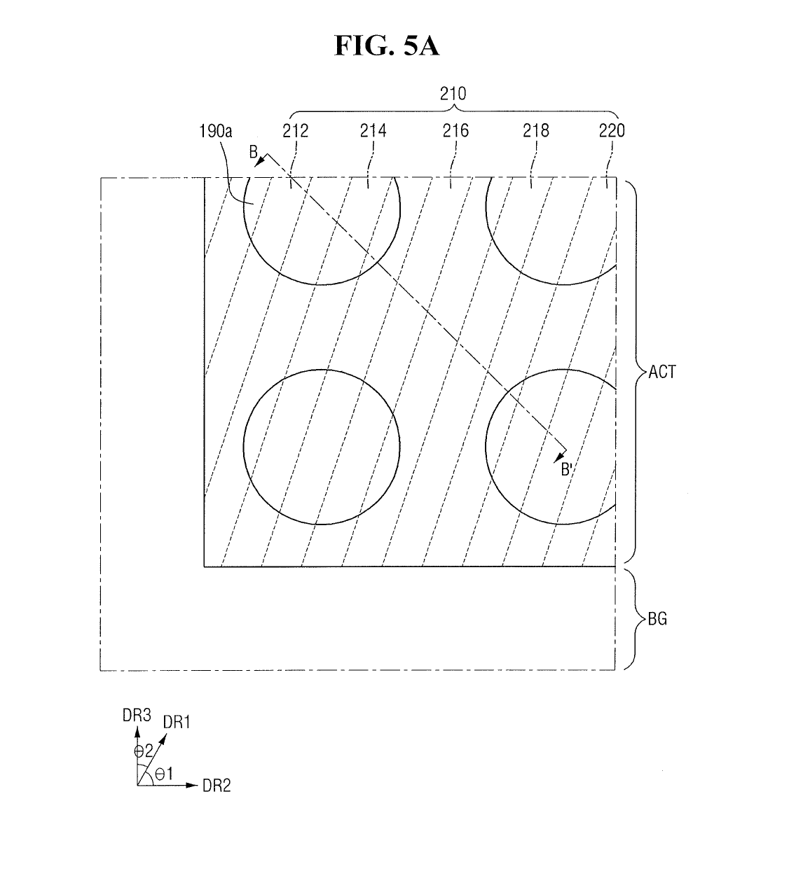

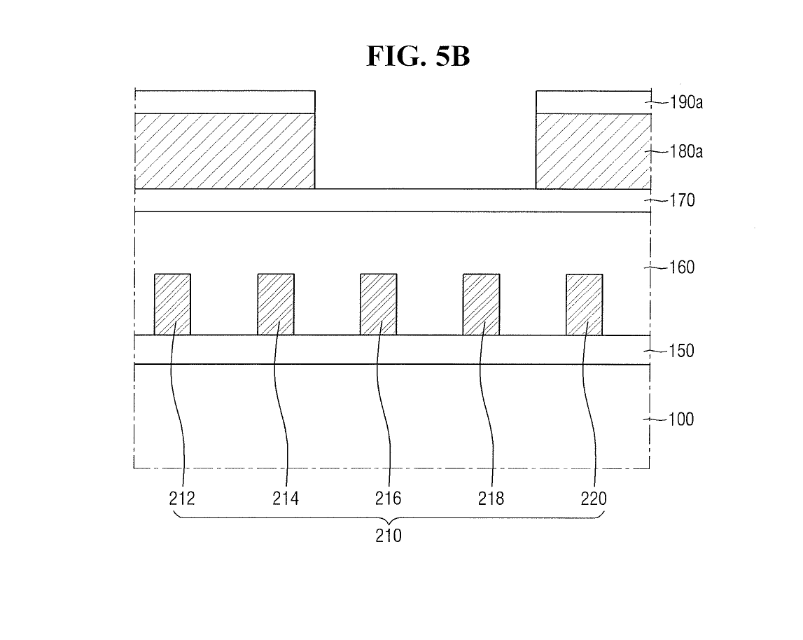

Referring to FIGS. 5A and 5B, the second mask layers 180 and 190 are patterned using the photosensitive layer pattern 200 as a mask, thereby partially exposing an upper surface of the first mask layer 170. The patterning of the second mask layers 180 and 190 may result in the formation of second mask layer patterns 180a and 190a. The photosensitive layer pattern 200 may be removed by an etching process or a subsequent process.

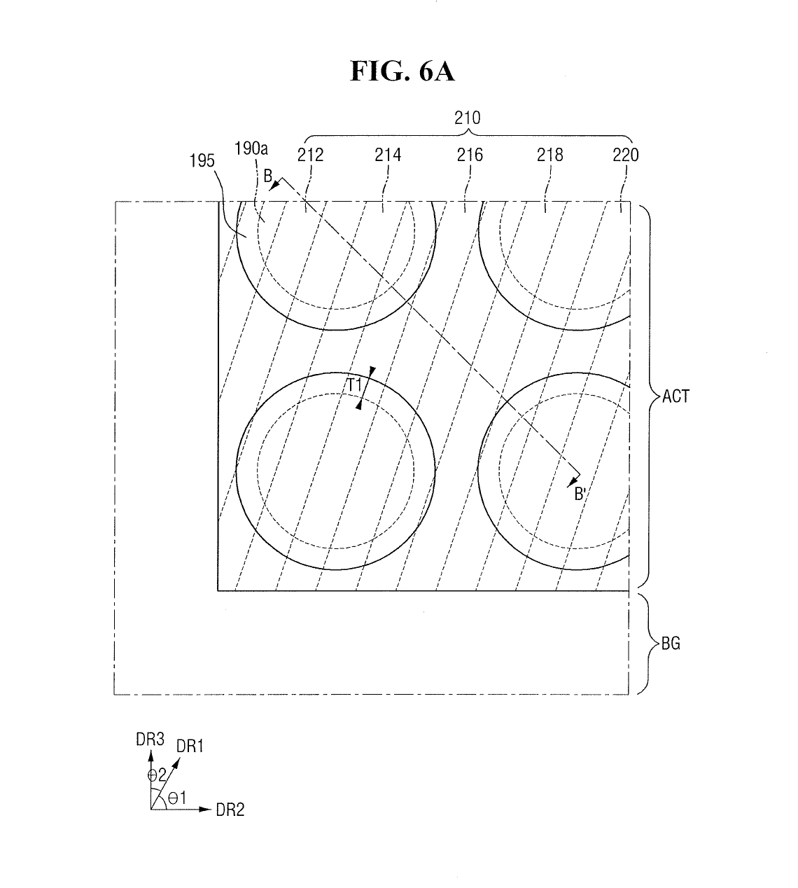

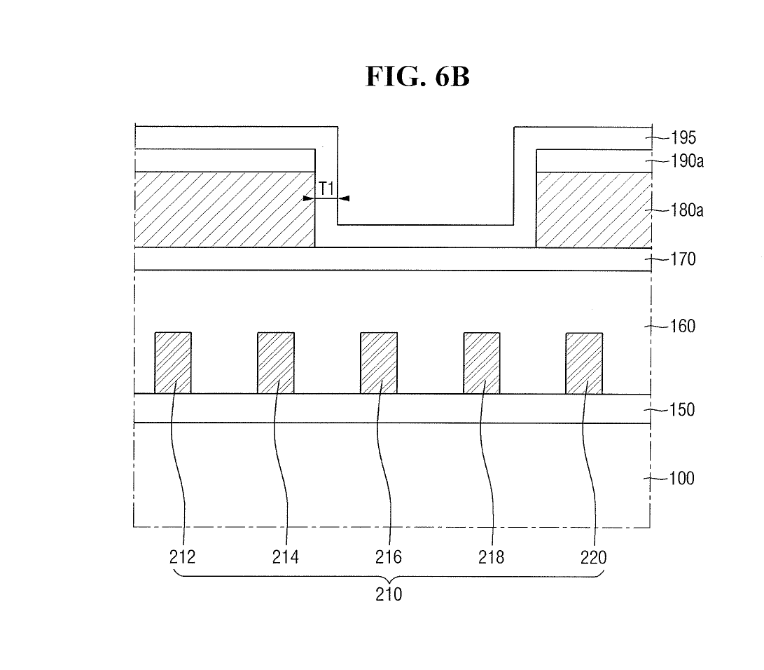

Referring to FIGS. 6A and 6B, a first spacer layer 195 is, e.g., conformally, formed to cover the second mask layer patterns 180a and 190a and the first mask layer 170. In detail, the first spacer layer 195 may cover upper surfaces and sidewalls of the second mask layer patterns 180a and 190a, and the exposed upper surface of the first mask layer 170.

The first spacer layer 195 may include at least one of, e.g., silicon nitride (SiN), silicon oxynitride (SiON), silicon oxide (SiO₂), silicon oxycarbonitride (SiOCN), silicon carbon nitride (SiCN), and a combination thereof. The first spacer layer 195 may be formed by ALD or CVD. A thickness T1 of the first spacer layer 195 may be determined in view of the size of spaces included in a semiconductor device according to an embodiment of the present disclosure.

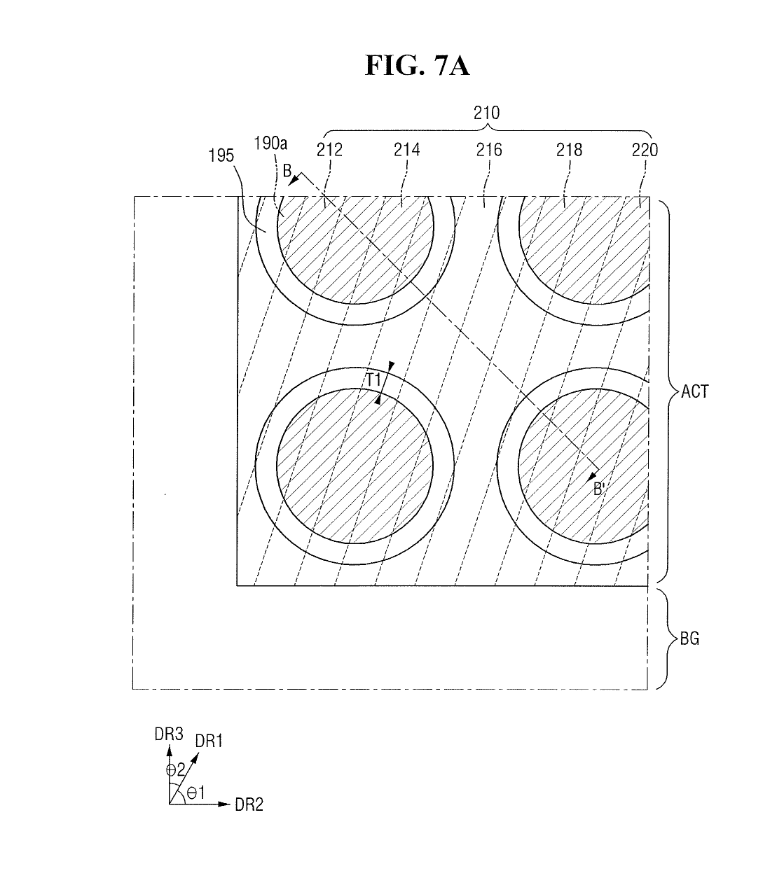

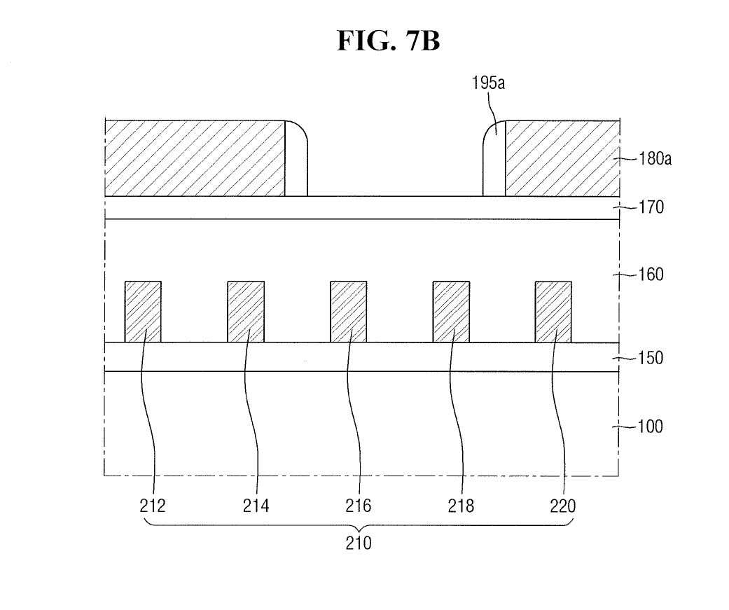

Referring to FIGS. 7A and 7B, the first spacer layer 195 is partially removed to expose the upper surfaces of the second mask layer pattern 180a and the first mask layer 170 and form first spacers 195a. The partial removal of the first spacer layer 195 may be performed by, but is not limited to, an etch-back process.

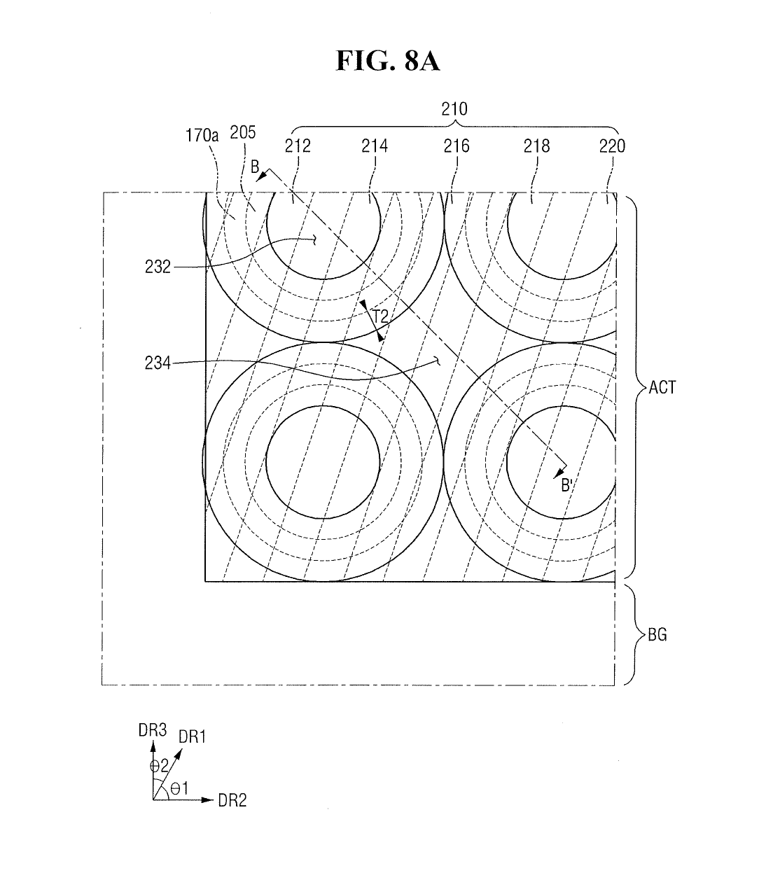

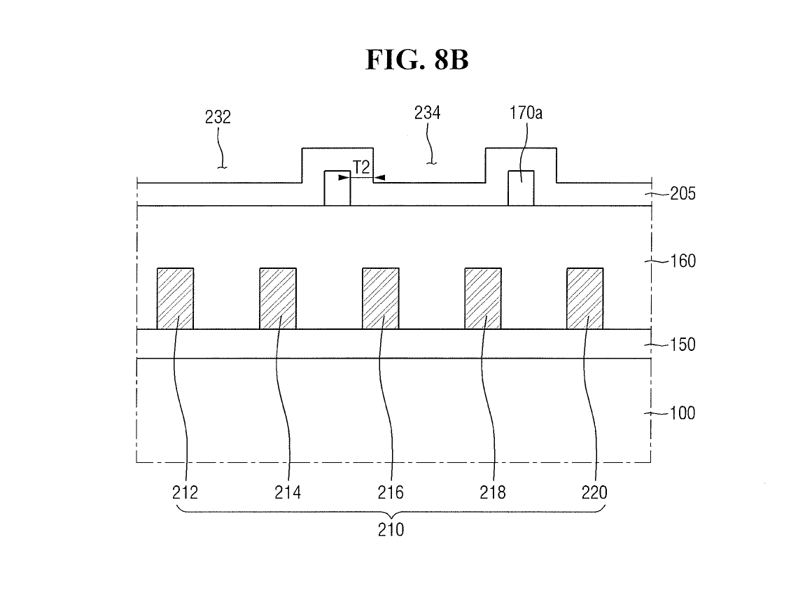

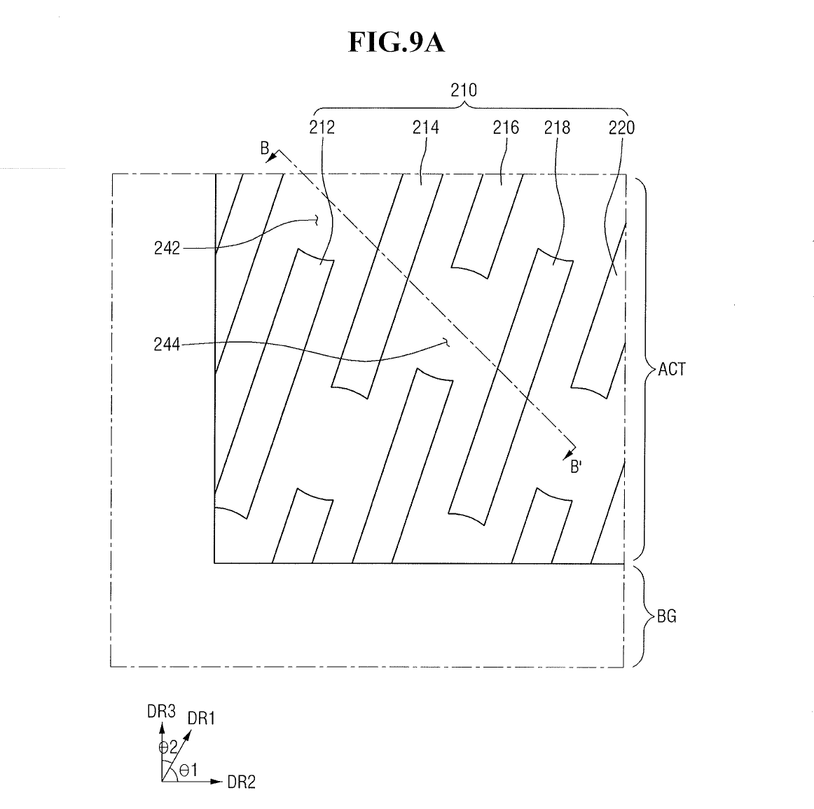

Referring to FIGS. 8A and 8B, the second mask layer pattern 180a may be removed, such that the first mask layer 170 is patterned using the first spacers 195a as an etch mask, thereby forming first mask layer patterns 170a. Then, a second spacer layer 205 is formed to cover the first mask layer patterns 170a and the first mask layer 160.

The second spacer layer 205 may include at least one of, e.g., silicon nitride (SiN), silicon oxynitride (SiON), silicon oxide (SiO₂), silicon oxycarbonitride (SiOCN), silicon carbon nitride (SiCN), and a combination thereof. The second spacer layer 205 may be formed by ALD or CVD. A thickness T2 of the second spacer layer 205 may be determined in view of the size of spaces included in a semiconductor device according to an embodiment of the present disclosure. The thickness T1 of the first spacer layer 195 and the thickness T2 of the second spacer layer 205 may be different.

The first mask layer patterns 170a and part of the second spacer layer 205 may overlap a second bar 214 and a fourth bar 218 (FIG. 8A). The formation of the second spacer layer 205 may define a first trench 232 and a second trench 234. Here, the second trench 234 may be a trench self-aligned by the first mask layer patterns 170a and the second spacer layer 205. A horizontal cross-section of the second trench 234, as viewed from a top view, may have four cusps (FIG. 8A).

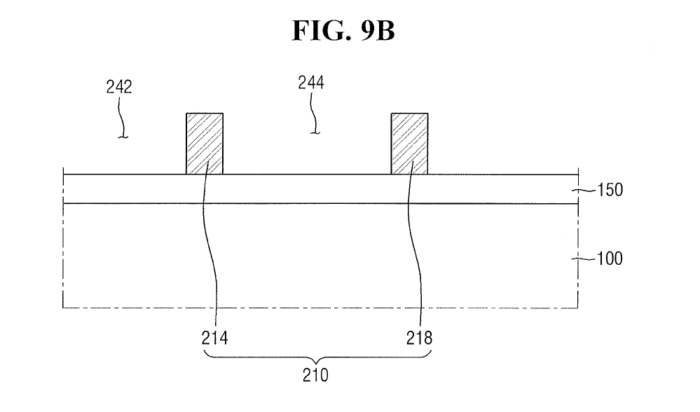

Referring to FIGS. 9A and 9B, the second spacer layer 205 is partially removed to expose the upper surfaces of the first mask layer pattern 170a and the first mask layer 160 and form second spacer (not shown) on side surfaces of the first mask layer pattern 170a. Thereafter, the first mask layer 160 and the bars 210 are patterned using the first mask layer patterns 170a and the second spacer as an etch mask, thereby forming bar patterns 214 and 218. While the horizontal cross-section of the second trench 234, as viewed in a top view (FIG. 8A) includes the cusps, the cusp portions may be etched more than other portions during the etching process. As a result, the second trench 244 may be patterned in a circular or oval shape, as illustrated in FIG. 9A.

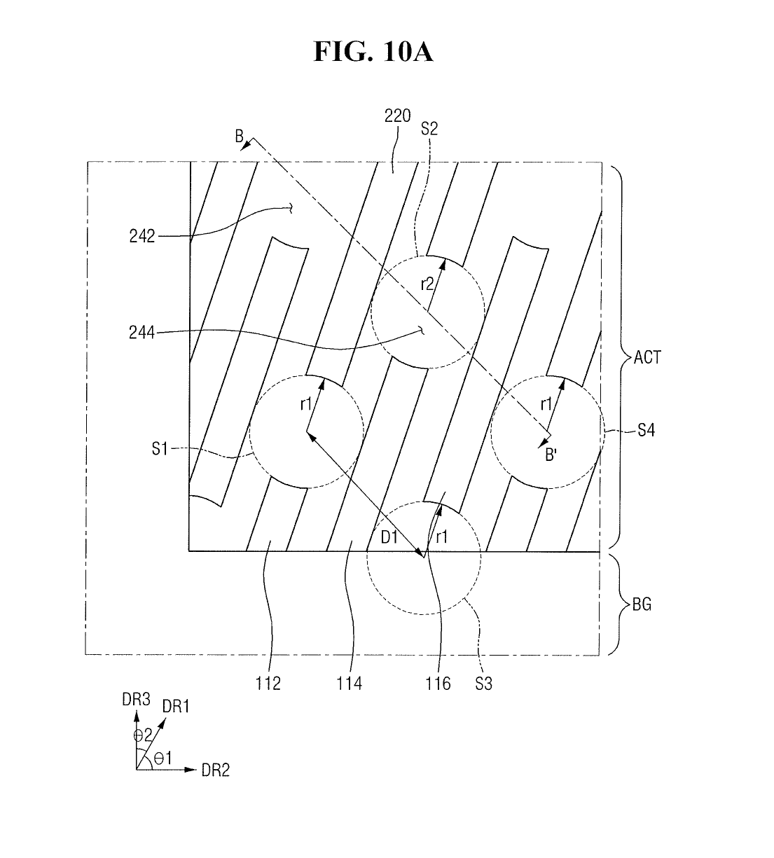

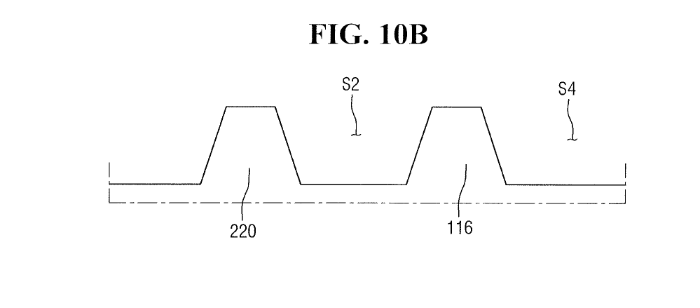

Referring to FIGS. 10A and 10B, the active layer 150, e.g., with the substrate 100, is patterned using the bar patterns 214 and 218, thereby forming active patterns 220 and 116, respectively. Accordingly, first through fourth spaces S1 through S4 may be formed. For example, as illustrated in FIGS. 9B and 10B, the second trench 244 may be modified during etching to define the second space S2 between the active patterns 116 and 220.

For example, as illustrated in FIGS. 10A-10B, the second space S2 and the third space S3 are spaces self-aligned by the active patterns 116 and 220. The radius r1 of the first space S1 and the radius r2 of the self-aligned second space S2 may be adjusted by controlling the thickness T1 of the first spacer layer 195 and the thickness T2 of the second spacer layer 205.

By way of summation and review, aspects of the present disclosure provide a semiconductor device which includes an active pattern trimmed by self-alignment. Aspects of the present disclosure also provide a method of manufacturing a semiconductor device, in which the active pattern is trimmed by self-alignment.

That is, in the method of manufacturing a semiconductor device according to the embodiment of the present disclosure, an uneven, e.g., nonlinear, interface may be defined between the cell area and the background area by self alignment of mask layer patterns, thereby providing a semiconductor device that is a long bar free device, e.g., including shorter active bars at the boundary area between the cell area and the background area as compared to active bars at an even, e.g., linear, interface between the cell area and the background area. The uneven interface between the cell area and the background area may be generated by a patterning process using a photosensitive layer pattern that is performed only once, e.g., resulting in a space filled with a background pattern extending from the background area into the cell area. Therefore, manufacturing costs can be saved. In addition, since the active layer, i.e., the active bar, is patterned using self-aligned spaces, the misalignment of active patterns can be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a cell area and a background area, the background area surrounding the cell area;
a plurality of active patterns in the cell area along a first direction, the active patterns being defined by a device isolation layer; and
a background pattern filling the background area to surround the cell area,
wherein the active patterns include:
a first active pattern most adjacent to an edge of the cell area, and
a second active pattern separated from the first active pattern in a second direction intersecting the first direction, the second active pattern being separated from the background area.

2. The semiconductor device as claimed in claim 1, further comprising a space between the second active pattern and the background area.

3. The semiconductor device as claimed in claim 2, wherein the space protrudes from the background area toward the cell area.

4. The semiconductor device as claimed in claim 3, wherein the background pattern fills the space.

5. The semiconductor device as claimed in claim 1, wherein the active patterns further comprise a third active pattern between the second active pattern and the first active pattern, the third active pattern contacting the background area.

6. The semiconductor device as claimed in claim 5, wherein a length of the third active pattern in the first direction is greater than a length of the first active pattern in the first direction.

7. The semiconductor device as claimed in claim 5, wherein the active patterns further comprise a fourth active pattern separated from the first active pattern in the first direction, an end of the first active pattern and an end of the fourth active pattern which faces the end of the first active pattern are concave toward respective centers of the first active pattern and the fourth active pattern.

8. The semiconductor device as claimed in claim 7, wherein the end of the first active pattern and the end of the fourth active pattern which faces the end of the first active pattern have a same radius of curvature.

9. The semiconductor device as claimed in claim 7, wherein the active patterns further comprise a fifth active pattern separated from the third active pattern in the first direction, wherein an end of the third active pattern and an end of the fifth active pattern which faces the end of the third active pattern have a same radius of curvature.

10. The semiconductor device as claimed in claim 1, wherein the first active pattern contacts the background area.

11. The semiconductor device as claimed in claim 1, wherein a length of the first active pattern in the first direction is smaller than a length of the second active pattern in the first direction.

12. A semiconductor device, comprising:
a substrate including a cell area and a background area, the background area surrounding the cell area;
a plurality of active patterns in the cell area of the substrate, the active patterns extending along a first direction and are separated from each other in the first direction; and
a first space and a second space among the plurality of active patterns, the plurality of active patterns with the first and second spaces being arranged alternately,
wherein at least one of the active patterns is separated from the background area by the second space.

13. The semiconductor device as claimed in claim 12, wherein the first space and the second space are arranged in a diagonal grid shape or a honeycomb shape.

14. The semiconductor device as claimed in claim 12, wherein a horizontal cross-section of each of the first space and the second space is circular or oval.

15. The semiconductor device as claimed in claim 14, wherein the horizontal cross-sections of the first space and the second space have different long radii and/or short radii.

16. A semiconductor device, comprising:
a substrate including a cell area and a background area, the background area surrounding the cell area;
a plurality of active patterns in the cell area along a first direction, the active patterns including:
a first active pattern most adjacent to an edge of the cell area, and
a second active pattern separated from the first active pattern in a second direction intersecting the first direction; and
a background pattern in the background area, a portion of the background pattern extending from the background area into the cell area to define a nonlinear boundary between the background area and the cell area, the portion of the background pattern extending into the cell area contacting the second active pattern.

17. The semiconductor device as claimed in claim 16, wherein a length of the first active pattern in the first direction is smaller than a length of the second active pattern in the first direction.

18. The semiconductor device as claimed in claim 16, wherein a surface of the second active pattern contacting the portion of the background pattern in the cell area is curved.

19. The semiconductor device as claimed in claim 16, further comprising a third active pattern between the second active pattern and the first active pattern, an interface between the third active pattern and the background area being substantially linear.

20. The semiconductor device as claimed in claim 19, wherein the portion of the background pattern extending into the cell area partially contacts the third active pattern.
